(19) United States
(12) Patent Application Publication
(10) Pub. No.: US 2015/0170891 A1
(43) Pub. Date: Jun. 18, 2015

(54) PARTICLE BACKFLOW PREVENTING PART AND SUBSTRATE PROCESSING APPARATUS

(71) Applicant: Tokyo Electron Limited, Tokyo (JP)

(72) Inventors: Masanori TAKAHASHI, Miyagi (JP); Tsuyoshi HIDA, Miyagi (JP); Noboru TAKEMOTO, Miyagi (JP); Hideaki YAKUSHIJI, Miyagi (JP); Lin ChiaHung, Hsin-chu City (TW); Akitoshi HARADA, Miyagi (JP)

(21) Appl. No.: 14/567,133

(22) Filed: Dec. 11, 2014

(30) Foreign Application Priority Data
Dec. 18, 2013 (JP) 2013-261467

(51) Int. Cl. H01J 37/34

(52) U.S. Cl. CPC H01J 37/3488; H01J 2237/3341; H01J 2237/3343

(57) ABSTRACT

A particle backflow preventing part, which is disposed inside of an evacuation pipe connecting a process chamber and an evacuation device, includes a first plate part, and a second plate part that has an opening and is spaced from the first plate part by a first gap and positioned closer to the evacuation device than the first plate part. The opening is covered by the first plate part in plan view.

### CROSS-REFERENCE TO RELATED APPLICATION

The present application is based upon and claims the benefit of priority of Japanese Patent Application No. 2013-261467, filed on Dec. 18, 2013, the entire contents of which are incorporated herein by reference.

### BACKGROUND OF THE INVENTION

1. Field of the Invention

An aspect of this disclosure relates to a particle backflow preventing part and a substrate processing apparatus.

2. Description of the Related Art

In a substrate processing apparatus including a process chamber connected to an evacuation device, it happens that particles flow backward (or rebound) from the evacuation device into the process chamber.

Japanese Laid-Open Patent Publication No. 2008-240701, for example, discloses a technology where a shielding device is provided between a process chamber and an evacuation device to prevent particles from entering the process chamber.

However, with the technology disclosed in Japanese Laid-Open Patent Publication No. 2008-240701, it is difficult to prevent particles from entering the process chamber and to maintain the evacuation efficiency at the same time.

### SUMMARY OF THE INVENTION

An aspect of this disclosure provides a particle backflow preventing part that is disposed inside of an evacuation pipe connecting a process chamber and an evacuation device. The particle backflow preventing part includes a first plate part, and a second plate part that has an opening and is spaced from the first plate part by a first gap and positioned closer to the evacuation device than the first plate part. The opening is covered by the first plate part in plan view.

### BRIEF DESCRIPTION OF THE DRAWINGS

FIG. 1 is a drawing illustrating an overall configuration of a substrate processing apparatus according to an embodiment;

FIG. 2 is an enlarged view of a part around an evacuation pipe of a substrate processing apparatus according to an embodiment;

FIGS. 3A and 3B are schematic diagrams of a particle backflow preventing part according to a first embodiment;

FIG. 4 is an enlarged view of a part around an evacuation pipe of a substrate processing apparatus according to a second embodiment;

FIGS. 5A and 5B are schematic diagrams of a particle backflow preventing part according to the second embodiment;

FIGS. 6A and 6B are graphs illustrating exemplary relationships between the number of particles deposited on a wafer and the diameter of the particles; and

FIG. 7 is a drawing used to describe a positional relationship between particles deposited on a wafer and an evacuation channel according to a first comparative example.

### DESCRIPTION OF THE PREFERRED EMBODIMENTS

Embodiments of the present invention are described below with reference to the accompanying drawings. In the specification and the drawings of the present application, the same reference number is assigned to substantially the same components, and repeated descriptions of those components are omitted.

### <Overall Configuration of Substrate Processing Apparatus 1>

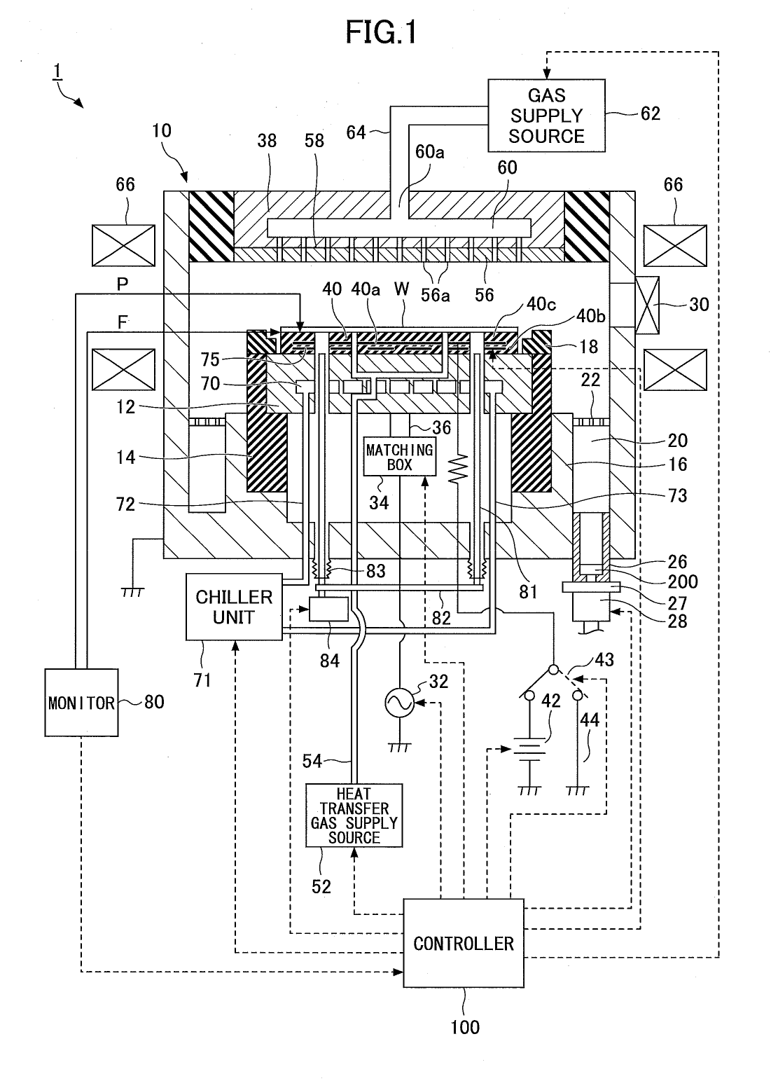

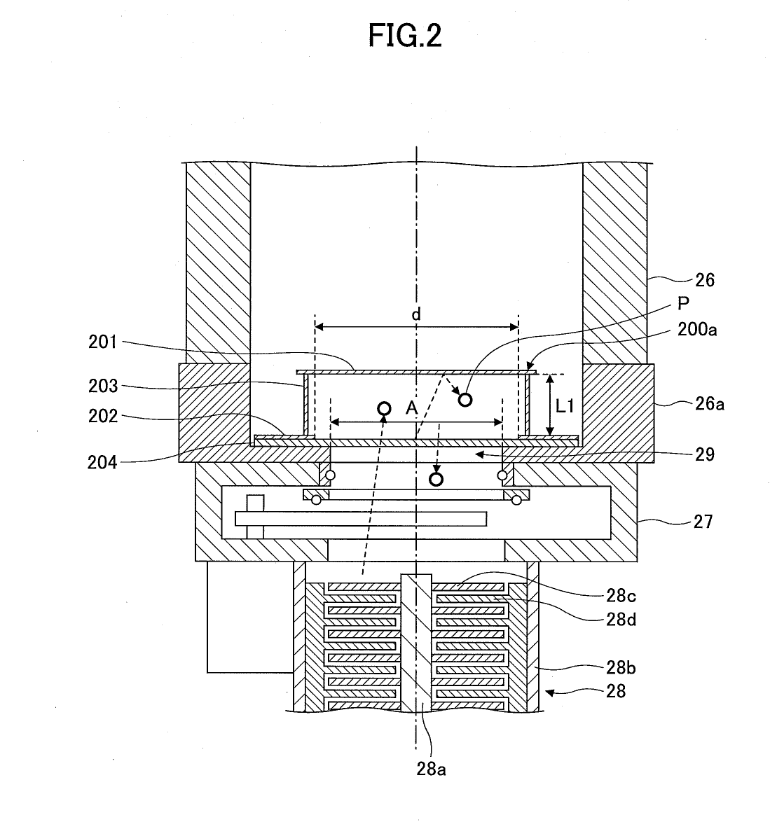

First, an overall configuration of a substrate processing apparatus 1 including a particle backflow preventing part 200 according to an embodiment of the present invention is described with reference to FIGS. 1 and 2.

FIG. 1 is a drawing illustrating an overall configuration of the substrate processing apparatus 1 according to an embodiment. FIG. 2 is an enlarged view of a part around an evacuation pipe 26 of the substrate processing apparatus 1 of the present embodiment. In the descriptions related to FIG. 2, the top of FIG. 2 is referred to as an “upper side” and the bottom of FIG. 2 is referred to as a “lower side”.

The substrate processing apparatus 1 of FIG. 1 is a reactive-ion-etching (RIE) substrate processing apparatus. The substrate processing apparatus 1 includes a cylindrical process chamber 10 made of, for example, a metal material such as aluminum or a stainless steel. The process chamber 10 is grounded. In the process chamber 10, plasma processing such as etching is performed on an object.

A mount table 12, on which a substrate such as a semiconductor wafer (which is here after referred to as a “wafer W”) is to be placed, is provided in the process chamber 10. The mount table 12 is comprised of, for example, aluminum and supported via a cylindrical holder 14 having insulating properties by a cylindrical support 16 that extends vertically upward from the bottom of the process chamber 10. A focus ring 18, which is comprised of, for example, quartz, is provided on an upper surface of the cylindrical holder 14 such that the focus ring 18 circularly surrounds an upper surface of the mount table 12.

An evacuation channel 20 is formed between an inner wall of the process chamber 10 and an outer wall of the cylindrical support 16. A circular baffle board 22 is placed in the evacuation channel 20. The evacuation channel 20 is connected via the evacuation pipe 26 to an evacuation device 28. Thus, the evacuation pipe 26 connects the process chamber 10 and the evacuation device 28.

As illustrated in FIG. 2, the evacuation pipe 26 includes a flange 26a. The flange 26a has an opening 29 with an inside diameter A. A pressure control valve 27 such as an auto pressure controller (APC) valve is provided between the flange 26a and the evacuation device 28. The pressure control valve 27 communicates with the opening 29, and controls the effective evacuation rate of the evacuation device 28.

The inside diameter of a part of the flange 26a at the junction with the pressure control valve 27 (i.e., in an area where the opening 29 is formed) is less than the inside diameter of other parts of the flange 26a. The opening 29 is formed in this part.

A protective screen 204 may also be provided at the bottom of the flange 26a where the opening 29 is formed. The protective screen 204 prevents, for example, screws used for maintenance from entering (or dropping into) the evacuation device 28. The diameter of the protective screen 204 is set at a value that is greater than the inside diameter A of the opening 29 of the flange 26a.

The particle backflow preventing part 200 of the present embodiment, which is described later, is provided inside of the flange 26a. The particle backflow preventing part 200 is disposed, for example, on the protective screen 204. When the protective screen 204 is not provided, the particle backflow preventing part 200 may be directly placed inside of the flange 26a without using the protective screen 204.

The evacuation device 28 may be implemented by a vacuum pump such as a turbo-molecular pump (TMP) including rotor blades 28c that rotate at a high speed.

Below, a configuration of the evacuation device 28 is described assuming that a TMP is used as the evacuation device 28.

As illustrated in FIG. 2, the TMP includes a rotation shaft 28a, a body 28b, the rotor blades 28c, and stator blades 28d.

The rotation shaft 28a is disposed vertically in FIG. 2, and is a central axis of rotation of the rotor blades 28c.

The body 28b is a cylindrical case that houses the rotation shaft 28a, the rotor blades 28c, and the stator blades 28d.

The rotor blades 28c protrude perpendicularly from the rotation shaft 28a. The rotor blades 28c are arranged at regular intervals along the same circumference of the outer surface of the rotation shaft 28 and protrude radially from the rotation shaft 28a to form a rotor blade group.

The stator blades 28d protrude perpendicularly from the inner surface of the body 28b toward the rotation shaft 28a. The stator blades 28d are arranged at regular intervals along the same circumference of the inner surface of the body 28b and protrude toward the rotation shaft 28a to form a stator blade group. Rotor blade groups 28c and stator blade groups 28d are arranged alternately. That is, each stator blade group 28d is disposed between two adjacent rotor blade groups 28c.

Also, the uppermost rotor blade group is disposed above the uppermost stator blade group. That is, the uppermost rotor blade group is positioned closer to the process chamber 10 than the uppermost stator blade group.

When a TMP as described above is used, a gas above the TMP is discharged at a high speed into a space below the TMP by rotating the rotor blades 28c at a high speed around the rotor shaft 28a.

A gate valve 30 is attached to a side wall of the process chamber 10. The gate valve 30 is opened and closed when the wafer W is carried into and out of the process chamber 10.

A high-frequency power source 32 for generating plasma is connected via a matching box 34 and a power supply rod 36 to the mount table 12. The high-frequency power source 32 supplies high-frequency power of, for example, 60 MHz to the mount table 12. Thus, the mount table 12 also functions as a lower electrode.

A shower head 38 is provided as the ceiling of the process chamber 10. The shower head 38 functions as an upper electrode that is at a ground potential. The high-frequency power for plasma generation is supplied from the high-frequency power source 32 to a “capacitor” formed between the mount table 12 and the shower head 38.

An electrostatic chuck 40 for holding the wafer W with electrostatic attraction is provided on an upper surface of the mount table 12. The electrostatic chuck 40 includes a sheet-shaped chuck electrode 40a made of a conductive film and a pair of dielectric layers 40b and 40c that sandwich the chuck electrode 40a.

A direct voltage source 42 is connected via a switch 43 to the chuck electrode 40a. When a voltage from the direct voltage source 42 is turned on, the electrostatic chuck 40 attracts and holds the wafer W with a Coulomb force.

When the voltage to the chuck electrode 40a is turned off, the chuck electrode 40a is connected via the switch 43 to a ground 44. In the descriptions below, it is assumed that the chuck electrode 40a is grounded when the voltage to the chuck electrode 40a is turned off.

A heat transfer gas supply source 52 supplies a heat transfer gas such as a He gas or an Ar gas via a gas supply line 54 to a back surface of the wafer W placed on the electrostatic chuck 40.

The shower head 38 at the ceiling of the chamber 10 includes an electrode plate 56 having multiple gas holes 56a, and an electrode support 58 that detachably supports the electrode plate 56. A buffer chamber 60 is formed in the electrode support 58. A gas supply source 62 is connected via a gas supply pipe 64 to a gas port 60a of the buffer chamber 60. With the above configuration, a desired gas can be supplied through the shower head 38 into the process chamber 10.

Multiple (e.g., three) support pins 81 are provided in the mount table 12. The support pins 81 raise and lower the wafer W to pass and receive the wafer W to and from an external conveying arm (not shown). The support pins 81 are caused to move up and down by a force of a motor 84 transmitted via a connecting part 82. Through holes are formed in the process chamber 10, and the support pins 81 pass through the through holes to the outside of the process chamber 10. Bottom bellows 83 are provided below the through holes to separate the vacuum space in the process chamber 10 from the outside space at an atmospheric pressure and thereby keep the process chamber 10 airtight.

Circular or concentric magnets 66 are provided around the process chamber 10. The magnets 66 are arranged one over the other. In the process chamber 10, a plasma generating space is formed between the shower head 38 and the mount table 12. In the plasma generating space, a vertical RF electric field is formed by the high-frequency power source 32, and high-density plasma is generated near the surface of the mount table 12 by a high-frequency discharge.

A refrigerant pipe 70 is provided in the mount table 12. A refrigerant at a predetermined temperature is supplied from a chiller unit 71 and circulated through a pipe 72, the refrigerant pipe 70, and a pipe 73. A heater 75 is embedded in the electrostatic chuck 40. With the chiller unit 71 for cooling and the heater 75 for heating, the processing temperature of the wafer W on the electrostatic chuck 40 is adjusted to a desired value.

A controller 100 controls components of the substrate processing apparatus 1 such as the gas supply source 62, the heater 75, the direct voltage source 42, the switch 43, the matching box 34, the high-frequency power source 32, the heat transfer gas supply source 52, the motor 84, and the chiller unit 71. The controller 100 is also connected to a host computer (not shown).

The controller 100 includes a central processing unit (CPU), a read-only memory (ROM), and a random access memory (RAM) that are not shown. The CPU performs plasma processing according to various recipes stored in storage areas such as the ROM and RAM.

A recipe includes apparatus control information corresponding to process conditions. For example, the apparatus control information includes process time, temperatures in the process chamber 10 (e.g., an upper electrode temperature, a temperature of a side wall of the process chamber 10, and an ESC temperature), a pressure (gas discharge), high-frequency power and voltage, process gas flow rates, and heat transfer gas flow rates.

To perform substrate processing such as etching with the substrate processing apparatus 1 configured as described above, the gate valve 30 is opened, and then the wafer W held on a conveying arm is carried into the process chamber 10. Next, the wafer W is raised above the conveying arm by the support pins 81 protruding from the surface of the electrostatic chuck 40, and is held on the support pins 81.

Then, after the conveying arm is moved out of the process chamber 10, the support pins 81 are retracted into the electrostatic chuck 40 to place the wafer W on the electrostatic chuck 40.

After the wafer W is carried into the process chamber 10, the gate valve 30 is closed, an etching gas is supplied from the gas supply source 62 into the process chamber 10 at a predetermined rate, and the pressure in the process chamber 10 is decreased by the pressure control valve 27 and the evacuation device 28 to a predetermined value. High-frequency power with a predetermined power level is supplied from the high-frequency power source 32 to the mount table 12.

Also, a voltage is applied from the direct voltage source 42 to the chuck electrode 40a of the electrostatic chuck 40 to hold the wafer W on the electrostatic chuck 40. Further, a heat transfer gas is supplied to the back surface of the wafer W electrostatically-attracted to the electrostatic chuck 40.

The etching gas is introduced via the shower head 38 into the process chamber 10 like a shower, and is ionized by the high-frequency power supplied from the high-frequency power source 32 to generate plasma in the plasma generating space between the upper electrode (the shower head 38) and the lower electrode (the mount table 12). The principal surface of the wafer W is etched by radicals and ions in the generated plasma.

When detaching the wafer W from the electrostatic chuck 40 after the plasma etching, the supply of the heat transfer gas is stopped and an inert gas is introduced into the process chamber 10 to maintain the pressure in the process chamber 10 at a predetermined value. In this state, a voltage with opposite polarity, which is opposite to the polarity of the voltage applied to the chuck electrode 40a during the plasma etching, is applied to the chuck electrode 40a and then turned off to perform a diselectrification process for removing charges on the electrostatic chuck 40 and the wafer W.

Next, the support pins 81 are moved upward to raise the wafer W from the electrostatic chuck 40 and thereby detach the wafer W from the electrostatic chuck 40. Then, the gate valve 30 is opened, the conveying arm is moved into the process chamber 10, and the support pins 81 are lowered so that the wafer W is held on the conveying arm. The conveying arm is moved out of the process chamber 10, and the next wafer W is carried into the process chamber 10 by the conveying arm. The above process is repeated to process multiple wafers W in succession.

### First Embodiment

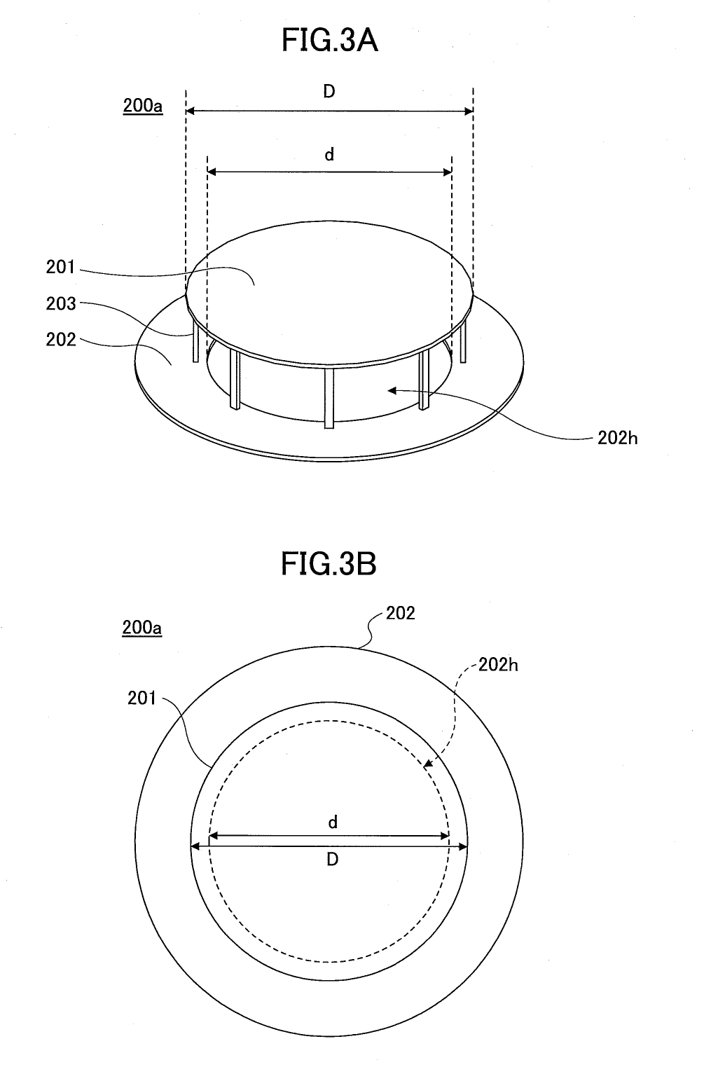

Next, a particle backflow preventing part 200a according to a first embodiment is described with reference to FIGS. 2, 3A, and 3B.

FIG. 3A is a perspective view and FIG. 3B is a plan view of the particle backflow preventing part 200a of the first embodiment.

As illustrated by FIGS. 3A and 3B, the particle backflow preventing part 200a of the first embodiment includes a first plate part 201 and a second plate part 202 having an opening 202h. The second plate part 202 is spaced from the first plate part 201 by a first gap L1 and positioned closer to the evacuation device 28 than the first plate part 201 (see FIG. 2).

Also, as illustrated by FIG. 3B, the opening 202h of the second plate part 202 is covered by the first plate part 201 in plan view.

Here, “plan view” indicates a view of the particle backflow preventing part 200a seen from a direction that is perpendicular to a surface of the first plate part 201 closer to the process chamber 10 (i.e., from the upper side in FIG. 2).

The first plate part 201 and the second plate part 202 are preferably made of a material that has a heat resistance and a corrosion resistance to plasma and acid. Also, the first plate part 201 and the second plate part 202 are preferably made of a material that provides sufficient rigidity even when used in a thin-plate form, can be easily welded, and is unlikely to cause arcing.

Examples of materials for the first plate part 201 and the second plate part 202 include metals such as stainless steel and aluminum, and ceramics.

It is also preferable to coat such a material with a coating agent including nickel and fluorine. This makes it possible to further improve the heat resistance, the corrosion resistance to plasma and acid, and the rigidity, and makes it possible to prevent by-products generated in the process chamber 10 from adhering to or being deposited on the first plate part 201 and the second plate part 202.

The first plate part 201 and the second plate part 202 may be made of the same material or different materials.

As the first plate part 201, for example, a discoidal part shaped like a disk in plan view may be used. However, the present invention is not limited to this example. The shape of the first plate part 201 may be selected depending on the shape of a place where the particle backflow preventing part 200a is disposed. For example, a plate part having a rectangular shape or an oval shape in plan view may be used for the first plate part 201.

As the second plate part 202, for example, an annular part with the opening 202h having a circular shape in plan view may be used. However, the present invention is not limited to this example. The shape of the second plate part 202 may be selected depending on the shape of a place where the particle backflow preventing part 200a is installed. For example, a plate part having a rectangular shape in plan view may be used for the second plate part 202.

Also, the second plate part 202 may have one opening 202h or multiple openings 202h. When multiple openings 202h are formed in the second plate part 202, all of the openings 202h are covered by the first plate part 201 in plan view.

Further, although the opening 202h of the second plate part 202 in the example of FIGS. 3A and 3B has a circular shape, the present invention is not limited to this example, and the opening 202h may have a rectangular shape or an oval shape.

As described above, the opening 202h of the second plate part 202 is covered by the first plate part 201 in plan view. In other words, a diameter d of the opening 202h of the second plate part 202 is set at a value that is less than a diameter D of the first plate part 201.

Also, the diameter d of the opening 202h of the second plate part 202 and the diameter D of the first plate part 201 are preferably set to satisfy a relational expression (1) below.

1≦D/d≦1.38 expression (1)

Also, the diameter d of the opening 202h of the second plate part 202 and the first gap L1 are preferably set to satisfy a relational expression (2) below.

0.49≦L1/d≦0.74 expression (2)

Using the particle backflow preventing part 200a satisfying the relationship of the expression (1) and/or the relationship of the expression (2) makes it possible to suppress the entry of particles into the process chamber 10 without reducing the efficiency of evacuating the substrate processing apparatus 1 with the evacuation device 28.

Also, in the particle backflow preventing part 200a of the first embodiment, for example, the first plate part 201 and the second plate part 202 are disposed parallel to each other. The particle backflow preventing part 200a may include rod-shaped parts 203 that for example extend, perpendicular to the first plate part 201, from a surface of the first plate part 201 facing the second plate part 202 to a surface of the second plate part 202 facing the first plate part 201. The rod-shaped parts 203 connect the first plate part 201 and the second plate part 202, and support the first plate part 201 when the second plate part 202 is placed on the flange 26a.

The rod-shaped parts 203 may have a predetermined length, or may be configured to be extendable and retractable. The degree of change in evacuation efficiency and the effect of preventing the entry of particles into the process chamber 10 resulting from the installation of the particle backflow preventing part 200a may depend on the length of the rod-shaped parts 203 (i.e., the first gap L1) and the diameter and length of the evacuation pipe 26 of the substrate processing apparatus 1. However, with the rod-shaped parts 203 configured to be extendable and retractable, it is possible to adapt the particle backflow preventing part 200a for various types of substrate processing apparatuses 1.

The first plate part 201 and the second plate part 202 may be connected by one rod-shaped part 203 or multiple rod-shaped parts 203. Connecting the first plate part 201 and the second plate part 202 by multiple rod-shaped parts 203 makes it possible to improve the strength of the particle backflow preventing part 200a.

Similarly to the first plate part 201 and the second plate part 202, the rod-shaped parts 203 preferably have a heat resistance and a corrosion resistance to plasma and acid. Also, the rod-shaped parts 203 are preferably made of a material that provides sufficient rigidity even when used in a thin-plate form, can be easily welded, and is unlikely to cause arcing.

Examples of materials for the rod-shaped parts 203 include metals such as stainless steel and aluminum, and ceramics. It is also preferable to coat such a material with a coating agent including nickel and fluorine. This makes it possible to further improve the heat resistance, the corrosion resistance to plasma and acid, and the rigidity, and makes it possible to prevent by-products generated in the process chamber 10 from adhering to or being deposited on the rod-shaped parts 203.

When the particle backflow preventing part 200a of the first embodiment is used for the substrate processing apparatus 1, the particle backflow preventing part 200a is placed on the protective screen 204 as illustrated in FIG. 2 (or on the bottom surface of the flange 26a when the protective screen 204 is not provided). In this case, the particle backflow preventing part 200a is disposed such that a surface of the second plate part 202, which is opposite to the surface facing the first plate part 201, contacts the protective screen 204. That is, the second plate part 202 is positioned closer to the evacuation device 28 and spaced from the first plate part 201 by the first gap L1.

Next, advantageous effects of the particle backflow preventing part 200a of the first embodiment are described with reference to FIG. 2. In FIG. 2, dotted arrow lines indicate exemplary traces of particles P.

As illustrated in FIG. 2, some of the particles P discharged from the process chamber 10 and reaching the evacuation device 28 may collide with the rotor blades 28c rotating at a high speed and rebound toward the process chamber 10. As a result, the rebounded particles P enter the process chamber 10 via the evacuation pipe 26.

However, with the particle backflow preventing part 200a of the first embodiment installed in the substrate processing apparatus 1, the opening 202h of the second plate part 202 is covered by the first plate part 201 in plan view. With this configuration, the particles P rebounded and entered the evacuation pipe 26 bounce back again after hitting (the lower surface of) the first plate part 201 and fall toward the evacuation device 28 (toward the lower side in FIG. 2). Thus, the particle backflow preventing part 200a can cause the particles P rebounded from the rotor blades 28c of the evacuation device 28 to bounce back toward the evacuation device 28.

As described above, the particle backflow preventing part 200a of the first embodiment makes it possible to prevent the particles P rebounded from the rotor blades 28c of the evacuation device 28 from entering the process chamber 10. This in turn makes it possible to prevent the particles P from adhering to a surface of the wafer W on which RIE processing is performed in the substrate processing apparatus 1, and thereby makes it possible to prevent, for example, short circuits and to improve the yield of substrate processing. Also, the particle backflow preventing part 200a makes it possible to reduce the frequency that the particles P adhere to the inner wall of the evacuation pipe 26, and thereby makes it possible to reduce the frequency of cleaning the evacuation pipe 26.

In addition to the rebounded particles P, the particle backflow preventing part 200a can also prevent deposits separated from the rotor blades 28c of the evacuation device 28 and flying toward the process chamber 10 from entering the process chamber 10.

In the particle backflow preventing part 200a, the first plate part 201 and the second plate part 202 are spaced from each other by the first gap L1. With this configuration, the evacuation efficiency of the evacuation device 28 is almost not reduced by the particle backflow preventing part 200a. Thus, it is also an advantage of the particle backflow preventing part 200a that installing the particle backflow preventing part 200a almost does not influence substrate processing.

### Second Embodiment

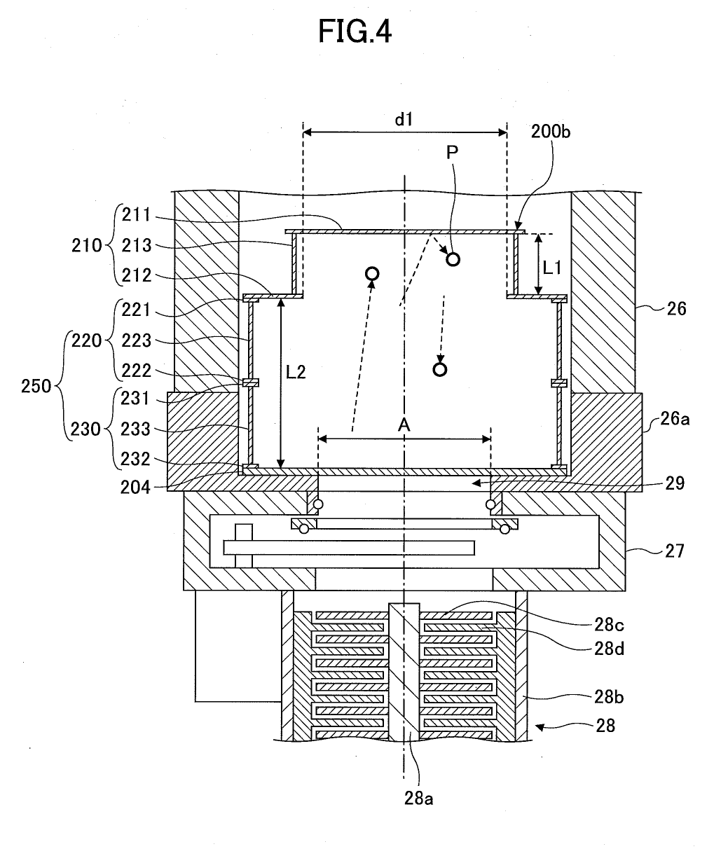

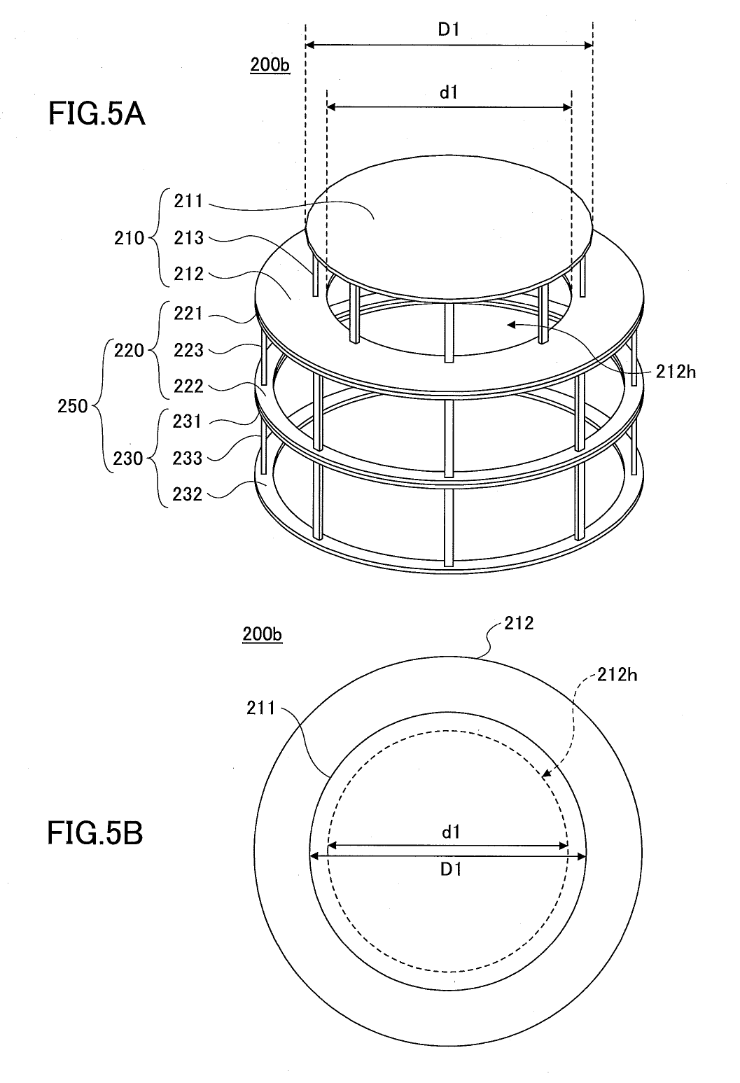

Next, a particle backflow preventing part 200b according to a second embodiment is described with reference to FIGS. 4, 5A, and 5B. The particle backflow preventing part 200b of the second embodiment includes components of the particle backflow preventing part 200a of the first embodiment, and is different from the particle backflow preventing part 200a in that it also includes a support part 250 that is disposed closer to the evacuation device 28 than the second plate part 202 and supports the second plate part 202.

FIG. 4 is an enlarged view of a part around the evacuation pipe 26 of the substrate processing apparatus 1 of FIG. 1 in a case where the particle backflow preventing part 200b of the second embodiment is installed. FIG. 5A is a perspective view and FIG. 5B is a plan view of the particle backflow preventing part 200b of the second embodiment. In the descriptions related to FIG. 4, the top of FIG. 4 is referred to as an “upper side” and the bottom of FIG. 4 is referred to as a “lower side”.

As illustrated by FIG. 4 and FIG. 5A, the particle backflow preventing part 200b of the second embodiment includes an upper part 210, a middle part 220, and a lower part 230 that are arranged in this order from the side of the process chamber 10 (i.e., the upper side of FIG. 4).

The upper part 210 has a configuration similar to the configuration of the particle backflow preventing part 200a of the first embodiment.

The middle part 220 and the lower part 230 constitute the support part 250 for supporting the upper part 210.

Each of the above parts is described below.

Because the upper part 210 has a configuration similar to the configuration of the particle backflow preventing part 200a of the first embodiment, descriptions of the upper part 210 are omitted here. A first plate part 211, a second plate part 212 having an opening 212h, and first rod-shaped parts 213 in the second embodiment correspond, respectively, to the first plate part 201, the second plate part 202 having the opening 202h, and the rod-shaped parts 203 in the first embodiment. Also, a diameter d1 of the opening 212h and a diameter D1 of the first plate part 211 in the second embodiment correspond, respectively, to the diameter d of the opening 202h and the diameter D of the first plate part 201 in the first embodiment.

The middle part 220 includes a third plate part 221 having an opening, and a fourth plate part 222 that is spaced from the third plate part 221 by a predetermined gap and positioned closer to the evacuation device 28 than the third plate part 221. The middle part 220 also includes second rod-shaped parts 223 that connect the third plate part 221 and the fourth plate part 222.

Materials similar to those used for the components of the upper part 210 may be used for the third plate part 221, the fourth plate part 222, and the second rod-shaped parts 223. These parts may be made of the same material or different materials.

As the third plate part 221, for example, an annular part with an opening having a circular shape in plan view may be used. However, the present invention is not limited to this example. The shape of the third plate part 221 may be selected depending on the shape of a place where the particle backflow preventing part 200b is installed. For example, a plate part having a rectangular shape in plan view may be used for the third plate part 221.

As the fourth plate part 222, for example, an annular part with an opening having a circular shape in plan view may be used. However, the present invention is not limited to this example. The shape of the fourth plate part 222 may be selected depending on the shape of a place where the particle backflow preventing part 200b is installed. For example, a plate part having a rectangular shape in plan view may be used for the fourth plate part 222.

The diameter of the openings of the third plate part 221 and the fourth plate part 222 is preferably greater than the diameter of the opening 212h.

The particle backflow preventing part 200b of the second embodiment include the second rod-shaped parts 223 that for example extend, perpendicular to the third plate part 221, from a surface of the third plate part 221 facing the fourth plate part 222 to a surface of the fourth plate part 222 facing the third plate part 221. The second rod-shaped parts 223 connect the third plate part 221 and the fourth plate part 222.

The lower part 230 includes a fifth plate part 231 having an opening, and a sixth plate part 232 that is spaced from the fifth plate part 231 by a predetermined gap and positioned closer to the evacuation device 28 than the fifth plate part 231. The lower part 230 also includes third rod-shaped parts 233 that connect the fifth plate part 231 and the sixth plate part 232.

The lower part 230 may have, but is not limited to, a configuration similar to the configuration of the middle part 230. For example, plate parts constituting the middle part and plate parts constituting the lower part may have different shapes and may be composed of different materials.

When the particle backflow preventing part 200b of the second embodiment is used for the substrate processing apparatus 1, the particle backflow preventing part 200b is placed on the protective screen 204 as illustrated in FIG. 4 (or on the bottom surface of the flange 26a when the protective screen 204 is not provided). In this case, the particle backflow preventing part 200b is disposed such that a surface of the sixth plate part 232, which is opposite to the surface facing the fifth part plate 231, contacts the protective screen 204.

Next, advantageous effects of the particle backflow preventing part 200b of the second embodiment are described with reference to FIG. 4. In FIG. 4, dotted arrow lines indicate exemplary traces of particles P.

As illustrated in FIG. 4, some of the particles P discharged from the process chamber 10 and reaching the evacuation device 28 may collide with the rotor blades 28c rotating at a high speed and rebound toward the process chamber 10. As a result, the rebounded particles P enter the process chamber 10 via the evacuation pipe 26.

However, with the particle backflow preventing part 200b of the second embodiment installed in the substrate processing apparatus 1, the opening 212h of the second plate part 212 is covered by the first plate part 211 in plan view. With this configuration, the particles P rebounded and entered the evacuation pipe 26 bounce back again after hitting (the lower surface of) the first plate part 211 and fall toward the evacuation device 28 (toward the lower side in FIG. 2). Thus, the particle backflow preventing part 200b can cause the particles P rebounded from the rotor blades 28c of the evacuation device 28 to bounce back toward the evacuation device 28.

As described above, the particle backflow preventing part 200b of the second embodiment makes it possible to prevent the particles P rebounded from the rotor blades 28c of the evacuation device 28 from entering the process chamber 10. This in turn makes it possible to prevent the particles P from adhering to a surface of the wafer W on which RIE processing is performed in the substrate processing apparatus 1, and thereby makes it possible to prevent, for example, short circuits and to improve the yield of substrate processing.

Also, the particle backflow preventing part 200b makes it possible to reduce the frequency that the particles P adhere to the inner wall of the evacuation pipe 26, and thereby makes it possible to reduce the frequency of cleaning the evacuation pipe 26.

In addition to the rebounded particles P, the particle backflow preventing part 200b can also prevent deposits separated from the rotor blades 28c of the evacuation device 28 and flying toward the process chamber 10 from entering the process chamber 10.

In the particle backflow preventing part 200b, the first plate part 211 and the second plate part 212 are spaced from each other by the first gap L1. With this configuration, the evacuation efficiency of the evacuation device 28 is almost not reduced by the particle backflow preventing part 200b. Thus, it is also an advantage of the particle backflow preventing part 200b that installing the particle backflow preventing part 200b almost does not influence substrate processing.

Further, the particle backflow preventing part 200b is configured such that a second gap L2 is formed between the lower surface of the second plate part 212 and the upper surface of the protective screen 204 by the support part 250 composed of the middle part 220 and the lower part 230. This configuration makes it possible to prevent the decrease in the evacuation efficiency of the evacuation device 28 more effectively.

Also, the particle backflow preventing part 200b can be installed by stacking the upper part 210, the middle part 220, and the lower part 230 at an installation location. This makes it possible to easily install the particle backflow preventing part 200b even when a space leading to the installation location is narrow. Accordingly, this configuration makes it possible to reduce maintenance time necessary to install or remove the particle backflow preventing part 200b.

In the second embodiment, the particle backflow preventing part 200b includes one upper part 210, one middle part 220, and one lower part 230. However, the present invention is not limited to this embodiment. For example, the particle backflow preventing part 200b may include one upper part 210, multiple middle parts 220, and multiple lower parts 230. In other words, the support part 250 may be configured to be able to be extendable and retractable.

Next, an exemplary case where particles P are deposited on the wafer W using the substrate processing apparatus 1 with the particle backflow preventing part 200b of the second embodiment is described. Also, as a comparative example, a case where particles P are deposited using the substrate processing apparatus 1 not including the particle backflow preventing part 200b is described.

### Example

First, the gate valve 30 is opened, and the wafer W held on a conveying arm is carried into the process chamber 10. Next, the wafer W is raised above the conveying arm by the support pins 81 protruding from the surface of the electrostatic chuck 40, and is held on the support pins 81. Then, after the conveying arm is moved out of the process chamber 10, the support pins 81 are retracted into the electrostatic chuck 40 to place the wafer W on the electrostatic chuck 40.

After the wafer W is carried into the process chamber 10, the gate valve 30 is closed, and a voltage is applied from the direct voltage source 42 to the chuck electrode 40a of the electrostatic chuck 40 to hold the wafer W on the electrostatic chuck 40. Further, a heat transfer gas is supplied to the back surface of the wafer W electrostatically-attracted to the electrostatic chuck 40.

Next, a nitrogen (N2) gas is supplied from the gas supply source 62 into the process chamber 10 at a predetermined rate, and the pressure in the process chamber 10 is decreased by the evacuation device 28 and adjusted to a predetermined value by controlling the pressure control valve 27.

Then, from a port (not shown) provided in the evacuation tube 26, particles P with a diameter between 0.1 and 1.0 μm are introduced into the process chamber 10. This is to artificially generate particles P similar to those generated when etching is performed on the wafer W.

When detaching the wafer W from the electrostatic chuck 40 after a predetermined period of time, the supply of the heat transfer gas is stopped and an inert gas is introduced into the process chamber 10 to maintain the pressure in the process chamber 10 at a predetermined value. In this state, a voltage with opposite polarity, which is opposite to the polarity of the voltage having been applied to the chuck electrode 40a, is applied to the chuck electrode 40a and then turned off to perform a diselectrification process for removing charges on the electrostatic chuck 40 and the wafer W.

Next, the support pins 81 are moved upward to raise the wafer W from the electrostatic chuck 40 and thereby detach the wafer W from the electrostatic chuck 40. Then, the gate valve 30 is opened, the conveying arm is moved into the process chamber 10, and the support pins 81 are lowered so that the wafer W is held on the conveying arm. The conveying arm is moved out of the process chamber 10 to carry the wafer W out of the process chamber 10.

Next, the number of particles P on the wafer W carried out of the process chamber 10 is measured.

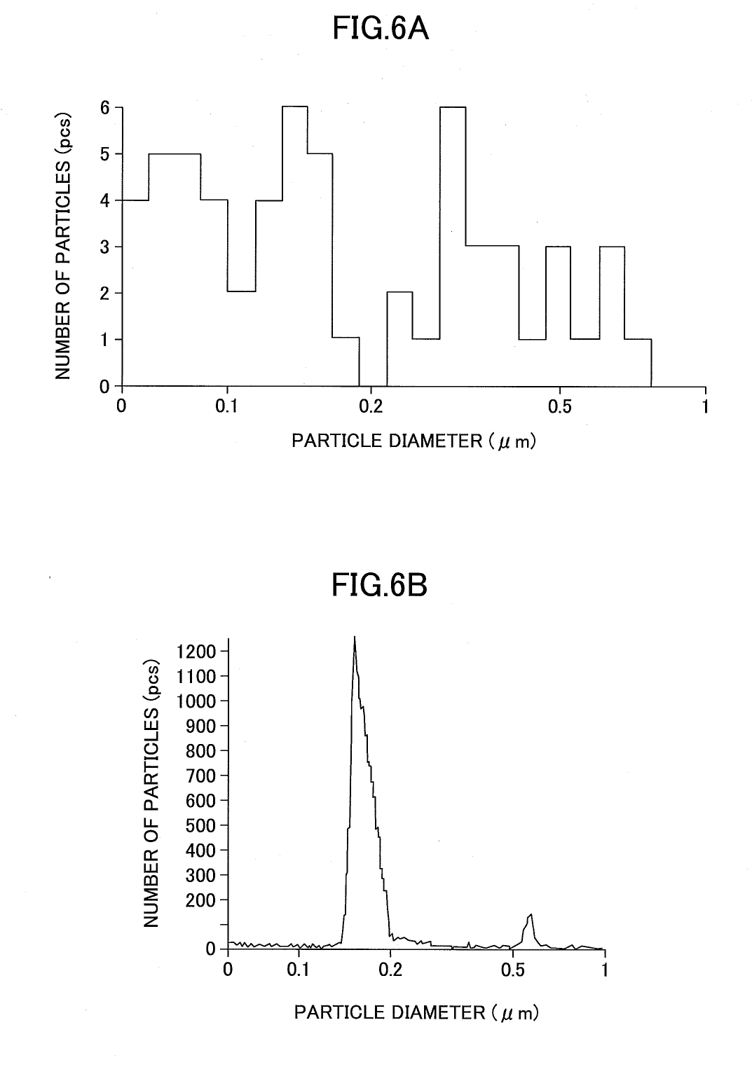

FIG. 6A is a graph illustrating a relationship between the number of particles P deposited on the wafer W and the diameter of the particles P that were measured after the above process was performed using the substrate processing apparatus 1 including the particle backflow preventing part 200b. In FIG. 6A, the horizontal axis indicates the diameter of particles P and the vertical axis indicates the number of particles P.

As illustrated by FIG. 6A, particles P with a diameter less than 1 μm were observed, and the number of particles P with a diameter greater than or equal to 0.06 μm was 61. It was also observed that the particles P were evenly deposited (not shown) on the surface of the wafer W without being concentrated in any particular area on the wafer W.

### Comparative Example

The number of particles P deposited on the wafer W was measured in the same manner as in the above EXAMPLE using the substrate processing apparatus 1 not including the particle backflow preventing part 200b. Except that the substrate processing apparatus 1 not including the particle backflow preventing part 200b was used, a process performed in the COMPARATIVE EXAMPLE is substantially the same as that performed in the EXAMPLE. Therefore, descriptions of the process are omitted here.

FIG. 6B is a graph illustrating a relationship between the number of particles P deposited on the wafer W and the diameter of the particles P that were measured after the same process as in the above EXAMPLE was performed using the substrate processing apparatus 1 not including the particle backflow preventing part 200b. In FIG. 6B, the horizontal axis indicates the diameter of particles P and the vertical axis indicates the number of particles P. Because the number of digits in the number of particles P measured in the COMPARATIVE EXAMPLE is three or more greater than that in the EXAMPLE, the scale of the vertical axis in FIG. 6B is different from the scale of the vertical axis in FIG. 6A.

As illustrated by FIG. 6B, compared with the EXAMPLE, a far more number of particles P were observed in the COMPARATIVE EXAMPLE. The diameter of the majority of observed particles P was between 0.15 μm and 0.2 μm. The number of particles P with a diameter greater than or equal to 0.06 μm was 16824.

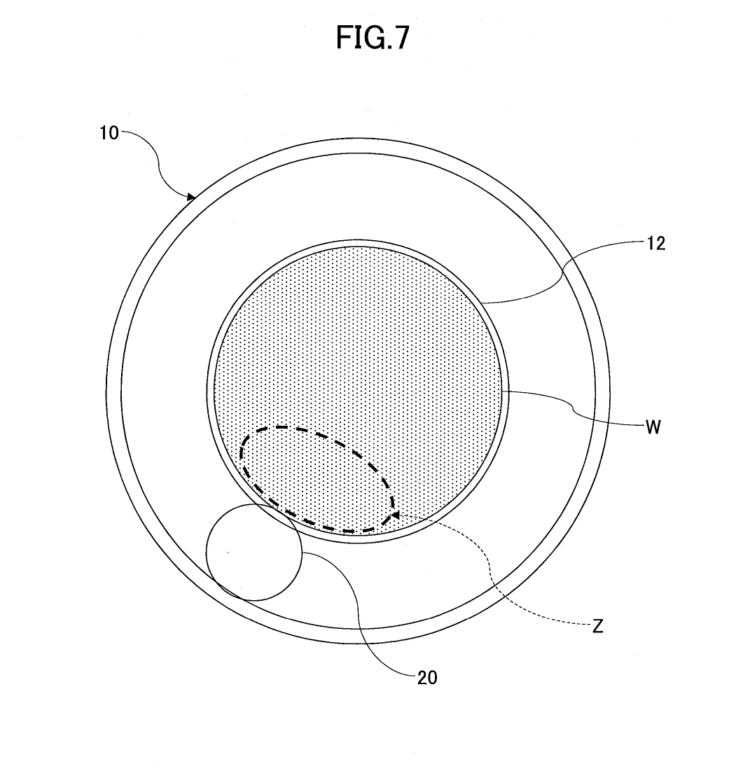

FIG. 7 illustrates a positional relationship between particles P deposited on the wafer W and the evacuation channel 20 in the substrate processing apparatus 1 not including the particle backflow preventing part 200b. In FIG. 7, for brevity, components such as the shower head 38 and the electrode plate 56 other than the mount table 12, the wafer W, and the evacuation channel 20 are omitted.

In the COMPARATIVE EXAMPLE, it was observed that the particles P were concentrated in an area Z illustrated in FIG. 7. This result indicates that the particles P flew back against an evacuation flow through the evacuation channel 20 into the process chamber 10 and were deposited on the wafer W.

Also, the opening degree of the pressure control valve 27 for controlling the pressure in the process chamber 10 at a predetermined value was the same in the EXAMPLE and the COMPARATIVE EXAMPLE. This indicates that installing the particle backflow preventing part 200b in the substrate processing apparatus 1 does not reduce the evacuation efficiency.

As described above, the number of particles P (with a diameter greater than or equal to 0.06 μm) deposited on the wafer W was reduced by 99.6% by installing the particle backflow preventing part 200b in the substrate processing apparatus 1. Thus, the particle backflow preventing part 200b can drastically reduce the number of particles P deposited on the wafer W as a result of rebounding without reducing the evacuation efficiency of the substrate processing apparatus 1.

As described above, an aspect of this disclosure provides a particle backflow preventing part that can prevent particles from entering a process chamber without reducing evacuation efficiency, and a substrate processing apparatus including the particle backflow preventing part.

The particle backflow preventing part 200 and the substrate processing apparatus 1 including the particle backflow preventing part 200 according to embodiments of the present invention are described above. However, the present invention is not limited to the specifically disclosed embodiments, and variations and modifications may be made without departing from the scope of the present invention.

In the above embodiments, it is assumed that the substrate processing apparatus 1 is an etching apparatus that is an example of a semiconductor device manufacturing apparatus. However, the present invention is not limited to the above described embodiments. For example, the substrate processing apparatus 1 may be a different type of semiconductor device manufacturing apparatus using plasma such as a chemical vapor deposition (CVD) apparatus or a physical vapor deposition (PVD) apparatus.

Also, the present invention may be applied to an ion implantation apparatus, a vacuum conveying apparatus, a heat treatment apparatus, an analyzer, an electron accelerator, a flat panel display (FPD) manufacturing apparatus, an etching apparatus used as a solar cell manufacturing apparatus or a physical quantity analyzing apparatus, and a reduced pressure processing apparatus such as a deposition apparatus including the evacuation device 28 having the rotor blades 28c.

In the above embodiments, the semiconductor wafer W is used as an example of a substrate. However, the above disclosure may also be applied to other types of substrates such as a glass substrate for an FPD and a substrate for a solar cell.

What is claimed is:

1. A particle backflow preventing part disposed inside of an evacuation pipe connecting a process chamber and an evacuation device, the particle backflow preventing part comprising:
a first plate part; and
a second plate part that has an opening, and is spaced from the first plate part by a first gap and positioned closer to the evacuation device than the first plate part,
wherein the opening is covered by the first plate part in plan view.

2. The particle backflow preventing part as claimed in claim 1, further comprising:
a rod-shaped part that connects the first plate part and the second plate part.

3. The particle backflow preventing part as claimed in claim 2, wherein
the first plate part and the second plate part are disposed parallel to each other; and
the rod-shaped part extends, perpendicular to the first plate part, from a surface of the first plate part facing the second plate part to a surface of the second plate part facing the first plate part.

4. The particle backflow preventing part as claimed in claim 2, wherein the rod-shaped part comprises a plurality of rod-shaped parts.

5. The particle backflow preventing part as claimed in claim 1, further comprising:
a support part that extends from the second plate part toward the evacuation device and supports the second plate part.

6. The particle backflow preventing part as claimed in claim 2, wherein the rod-shaped part is configured to be extendable and retractable.

7. The particle backflow preventing part as claimed in claim 5, wherein the support part is configured to be extendable and retractable.

8. The particle backflow preventing part as claimed in claim 1, wherein at least one of the first plate part and the second plate part is coated by a coating agent including nickel and fluorine.

9. The particle backflow preventing part as claimed in claim 1, wherein
the first plate part is a discoidal part; and
the second plate part is an annular part with the opening having a circular shape in plan view.

10. The particle backflow preventing part as claimed in claim 9, wherein when d indicates a diameter of the opening and L1 indicates the first gap, a relational expression “0.49≦L1/d≦0.74” is satisfied.

11. The particle backflow preventing part as claimed in claim 9, wherein when D indicates a diameter of the first plate part and d indicates a diameter of the opening, a relational expression “1≦D/d≦1.38” is satisfied.

12. A substrate processing apparatus, comprising:
a process chamber;
an evacuation device;
an evacuation pipe that connects the process chamber and the evacuation device;
a first plate part disposed inside of the evacuation pipe; and
a second plate part that has an opening, and is spaced from the first plate part by a first gap and positioned closer to the evacuation device than the first plate part,
wherein the opening is covered by the first plate part in plan view.

13. The substrate processing apparatus as claimed in claim 12, wherein the evacuation device includes a vacuum pump including rotor blades that rotate at a high speed.
